(19) United States
(12) Patent Application Publication
(10) Pub. No.: US 2012/0204928 A1
(43) Pub. Date: Aug. 16, 2012

(54) Solar Cell, Solar Module and Method for Manufacturing a Solar Cell

(75) Inventors: Martin Kutzer, Penig (DE); Bernd Bitnar, Bannewitz (DE); Harald Hahn, Dresden (DE); Andreas Krause, Radebeul (DE); Holger Neuhaus, Freiberg (DE)

(73) Assignee: SOLARWORLD INNOVATIONS GMBH, Freiberg (DE)

(21) Appl. No.: 13/367,378

(22) Filed: Feb. 7, 2012

(30) Foreign Application Priority Data
Feb. 15, 2011 (DE) 102011000753.9

(51) Int. Cl. H01L 31/0352; H01L 31/18; H01L 31/042

(52) U.S. Cl. 136/244; 136/255; 438/87; 257/E31.054

(57) ABSTRACT

In various embodiments, a solar cell is provided. The solar cell may include a base region doped with dopant of a first doping type; an emitter region doped with dopant of a second doping type, wherein the second doping type is opposite to the first doping type; a plurality of regions in the emitter region having an increased dopant concentration of the second doping type compared with the emitter region; and a plurality of metallic soldering pads, wherein each soldering pad is at least partially arranged on a region having an increased dopant concentration.

### CROSS REFERENCE TO RELATED APPLICATION

This application claims priority to German application No. DE 10 2011 000 753.9 filed on Feb. 15, 2011 which is hereby incorporated by reference in its entirety.

### TECHNICAL FIELD

Various embodiments relate to a solar cell, a solar module and a method to the production of a solar cell.

### BACKGROUND

A solar cell usually includes a substrate with a front side and a back side, wherein an electrically conductive contact structure is deposited on at least one of the two sides. The contact structure typically has a width of at least 100 μm whereas its thickness is only about 10 μm to 15 μm. A larger width of the contact structure leads to a reduction of the degree of effectiveness due to the shading increased by it, while a reduction of the width of the contact structure has the disadvantage as a consequence that the line resistance of the contact structure is increased. Furthermore, the current of the individual contact structures is normally brought together in so-called bus bars, causing another shading of the front side surface.

Besides the reduced performance by shading the contact structures normally produced from silver-containing silk-screen print paste represents a main cost portion of the solar cell manufacturing.

The interconnecting of solar cells generally happens by means of cell connectors, for example in the form of contact wires or contact ribbons which are soldered on the bus bars of the solar cell. The complete current is led through the contact wires or the contact ribbons. To keep the resistance losses as low as possible, it requires a certain total cross-sectional area of these contact wires or contact ribbons. This results in a loss by the shading on the front side.

To build an optimized solar module, the contact structures of the solar cell and the number and dimension of the contact wires or contact ribbons should be optimized in a combined manner.

In this case, there is an optimum for many (number n>10) and thin (diameter d<250 μm) contact wires or contact ribbons running parallel to each other.

A method for wiring solar cells is described in DE 102 39 845 C1.

Another method for the increase of the performance of a solar cell is the use of a selective emitter. Different conventional methods for the production of such a selective emitter have the disadvantages that the subsequent metallization must be aligned in a complex manner so that it is metallized exactly into the low-impedance regions (for example FhG ISE Synova-LCP/phosphorus acidic laser beam control).

### SUMMARY

In various embodiments, a solar cell is provided. The solar cell may include a base region doped with dopant of a first doping type; an emitter region doped with dopant of a second doping type, wherein the second doping type is opposite to the first doping type; a plurality of regions in the emitter region having an increased dopant concentration of the second doping type compared with the emitter region; and a plurality of metallic soldering pads, wherein each soldering pad is at least partially arranged on a region having an increased dopant concentration.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a flowchart in which a method for manufacturing a solar cell is illustrated in accordance with various embodiments;

FIG. 2 shows a flowchart in which a method for manufacturing a solar cell is illustrated in accordance with various embodiments;

FIG. 3 shows a top view of a solar cell is illustrated in accordance with various embodiments;

FIG. 4 shows a top view of a solar cell is illustrated in accordance with various embodiments;

FIG. 5 shows a top view of the solar cell of FIG. 3 with deposited cell connectors;

FIG. 6 shows a flowchart in which a method for manufacturing a solar cell is illustrated in accordance with various embodiments;

FIG. 7 shows a top view of an emitter region in accordance with various embodiments;

FIG. 8 shows a top view of an emitter region in accordance with various embodiments;

FIG. 9 shows a top view of an emitter region in accordance with various embodiments; and

FIG. 10 shows a cross sectional view of the solar cell of FIG. 3 in accordance with various embodiments;

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

In various embodiments, a solar is understood to be a device which converts radiation energy from predominantly visible light (e.g. at least a portion of the light in the visible wave length region from about 300 nm to about 1150 nm; it is to be noted that ultraviolet (UV) radiation and/or infrared (IR) radiation may also be additionally converted), for example from sunlight, directly into electrical energy by means of the so-called photovoltaic effect.

In various embodiments, a solar module is understood to be an electrically connectable device including a plurality of solar cells (which are connected with each other in series and/or parallel), and optionally with weather protection (for example glass), an embedment and a frame structure.

In various embodiments, a solar cell is clearly provided with selective emitter and reduced shading by local front side contacts (formed by the soldering pads, for example).

In various embodiments, the shading may be reduced by omitting the normally provided so-called bus bars and by reducing the cross-section of the electrically conductive contact structures (for example in the form of metallization lines). The costs for the silk-screen printing can also be reduced thereby, if for example a metal-containing, for example silver-containing silk-screen print paste is used for the production of the contact structures.

Various embodiments allow a further reduction of the used metal paste and thus a reduction of the power losses by shading and a reduction of the processing costs for manufacturing a solar cell and thus a solar module.

In various embodiments, a solar cell is provided which includes a selective emitter on its front side (also referred to as a sunny side), which takes over the task of a metallization net of a solar cell and which collects the electrical charge carriers (generated by the solar cell). The electrical contacting is then made by patterns of soldering pads which are formed from silk-screen print paste, for example, and are not connected with each other via metallization lines, for example.

Thus, on the one hand metal paste, for example silver paste, can be saved, and on the other hand, the processing costs can considerably be lowered and the shading of the solar cell can be reduced.

The thin soldering pads (in the following also referred to as pads) can then be contacted by means of wires or ribbons.

Another advantage of various embodiments can be seen in the relatively simple process control. The pad structures are considerably broader in comparison with the till now usual metal fingers so that an complex alignment which would be necessary, for example with a combination of the standard silk-screen print technology with a selective emitter, is omitted.

At first a substrate is provided in the context of the manufacturing of a solar cell in accordance with various embodiments.

The substrate may include or consist of a photovoltaic layer. As an alternative, at least one photovoltaic layer may be arranged over the substrate. The photovoltaic layer may include or consist of semiconductor material (such as, for example, silicon), compound semiconductor material (such as, for example, III-V-compound semiconductor material (such as, for example, GaAs), II-VI-compound semiconductor material (such as, for example, CdTe), I-III-V-compound semiconductor material (such as, for example, copper-indium-disulfide). As an additional alternative, the photovoltaic layer may include or consist of an organic material. In various exemplary embodiments, the silicon may include or consist of monocrystalline silicon, polycrystalline silicon, amorphous silicon and/or microcrystalline silicon. In various embodiments, the photovoltaic layer may include or consist of a semiconductor junction structure such as, for example, a pn-junction structure, a pin-junction structure, a Schottky-junction structure or the like. The substrate and/or the photovoltaic layer may be provided with a base doping of a first conductivity type.

In various embodiments, the base doping in the solar cell substrate may include a doping concentration (e.g. a doping of the first conductivity type, e.g. a doping with Boron (B))) in the range from about 10¹³ cm⁻³ to 10¹⁸ cm⁻³, e.g. in the range from about 10¹⁴ cm⁻³ to 10¹⁷ cm⁻³, e.g. in the range from about 10¹⁵ cm⁻³ to 2*10¹⁶ cm⁻³.

The solar cell substrate may be produced from a solar cell wafer and may have, for example, a round form such as, for example, a circular form or an elliptical form or a polygonal form such as, for example, a square form. In various embodiments, however, the solar cells of the solar module may also have a non-square form. In these cases, the solar cells of the solar module may be formed, for example, by separating (for example cutting) and thus dividing one or more solar cell(s) (also designated as standard solar cell in terms of their form) to result in a plurality of non-square or square solar cells. In various embodiments, provision may be made in these cases for performing adaptations of the contact structures in the standard solar cell; by way of example, rear-side transverse structures may additionally be provided.

In various embodiments, the solar cell may have the following dimensions: a width in a range of approximately 10 cm to approximately 50 cm, a length in a range of approximately 10 cm to approximately 50 cm, and a thickness in a range of approximately 100 μm to approximately 300 μm.

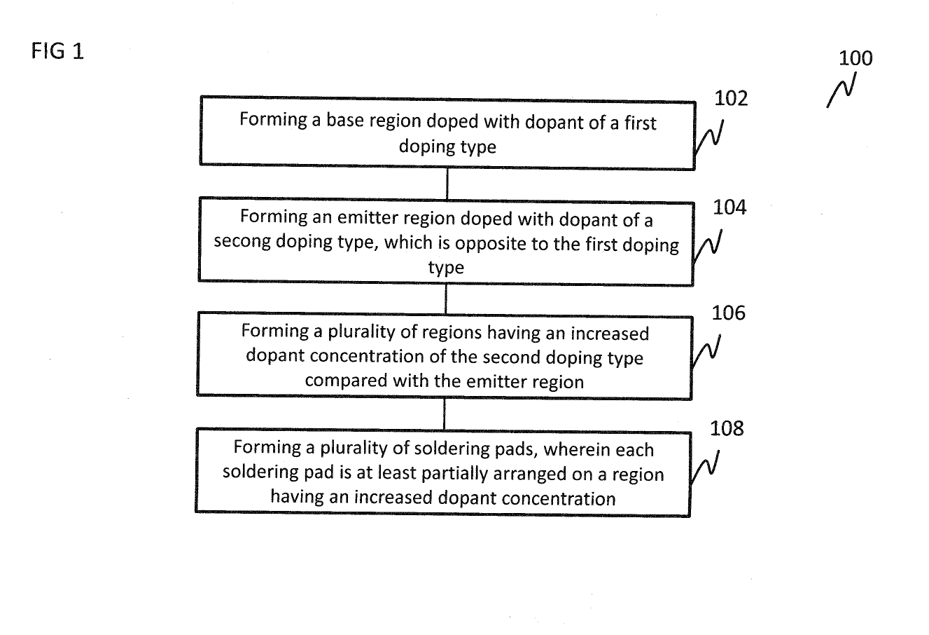

FIG. 1 shows a flowdiagram 100, in which a method for manufacturing a solar cell is illustrated in accordance with various embodiments.

In 102 a base region may be formed in the photovoltaic layer, e.g. doped with a dopant of a first doping type (also referred to as first conductivity type), e.g. doped with a dopant of a p-doping type, e.g. doped with a dopant of the III. main group of the periodic system, e.g. doped with Boron (B).

Furthermore, in 104, an emitter region may be formed, doped with a dopant of a second doping type (also referred to as second conductivity type), wherein the second conductivity type is opposite to the first conductivity type, e.g. doped with a dopant of an n-doping type, e.g. doped with a dopant of the V. main group of the periodic system, e.g. doped with Phosphorous (P).

Furthermore a plurality of region may be formed in the emitter region in 106 with compared with the emitter region increased dopant concentration of the second conductivity type. Illustratively, in various embodiments, the plurality of regions with increased dopant concentration represents a structure of selective emitters.

In various embodiments, an anti-reflection layer (for example including or consisting of silicon nitride) may optionally be deposited over the exposed upper surface of the emitter region.

Furthermore, a plurality of metallic soldering pads may be formed in 108, wherein each soldering pad is at least partly arranged on a region with increased dopant concentration (e.g. first deposited on the anti-reflection layer, followed by a through-firing process by means of which the metallic soldering pads are brought in physical contact with the region with increased dopant concentration).

In various embodiments, the regions with increased dopant concentration may be doped with a suitable dopant such as phosphorus. In various embodiments, the second conductivity type may be a p-conductivity type and the first conductivity type may be an n-conductivity type. As an alternative, in various embodiments, the second conductivity type may be an n-conductivity type and the first conductivity type may be a p-conductivity type.

In various embodiments, the regions with increased dopant concentration may be highly doped with dopant for doping with the second conductivity type with a surface doping concentration in the range from about 10¹⁸ cm⁻³ to about 10²² cm⁻³, e.g. with a doping concentration in the range from about 10¹⁹ cm⁻³ to about 10²² cm⁻³, e.g. with a doping concentration in the range from about 10²⁰ cm⁻³ to about 2*10²¹ cm⁻³. The sheet resistance in the highly doped region with the second conductivity type may be in the range from about 10 Ohm/sq to about 80 Ohm/sq, e.g. in the range from about 30 Ohm/sq to about 60 Ohm/sq, e.g. in the range from about 35 Ohm/sq to about 40 Ohm/sq.

Furthermore, in various embodiments, the other surface regions may be lightly doped with the second conductivity type with dopant for doping with the second conductivity type with a surface doping concentration in the range from about 10¹⁸ cm⁻³ to about 2*10²¹ cm⁻³, e.g. with a doping concentration in the range from about 10¹⁹ cm⁻³ to about 10²¹ cm⁻³, e.g. with a doping concentration in the range from about 5*10¹⁹ cm⁻³ to about 5*10²⁰ cm⁻³. The sheet resistance in the lightly doped regions with the second conductivity type may be in the range from about 60 Ohm/sq to about 300 Ohm/sq, e.g. in the range from about 70 Ohm/sq to about 200 Ohm/sq, e.g. in the range from about 80 Ohm/sq to about 120 Ohm/sq. Thus, by doing this, illustratively, a selective emitter is formed at least on the front side of the photovoltaic layer.

In various embodiments, the process of forming the selective emitter may be restricted on the front side of the solar cell substrate or may also refer to the doping on the back side of the solar cell substrate.

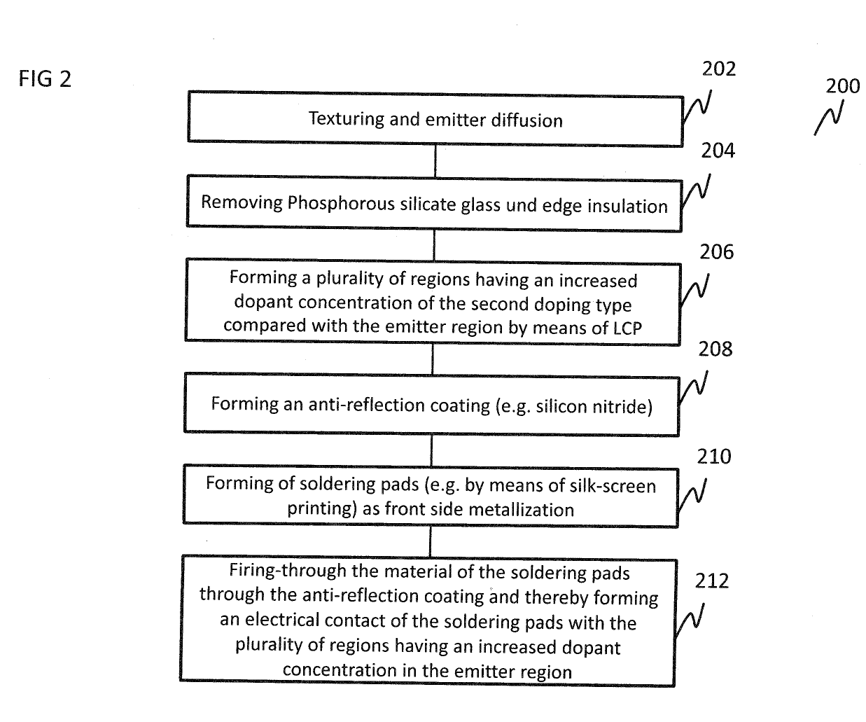

FIG. 2 shows a flowchart 200 in which a method for manufacturing a solar cell is illustrated in accordance with various embodiments.

In 202, the substrate with the photovoltaic layer may optionally be textured in way known as such (for example by means of anisotropical etching in an alkaline solution or by means of etching in a acidic solution or by means of sawing V trenches into the solar cell substrate) and may be subjected to a so-called emitter diffusion for example under use of an emulsion containing the dopant (for example phosphorus), which is deposited on the (exposed) front side of the photovoltaic layer. The emitter diffusion is carried out in various embodiments in a furnace, for example a continuous annealing furnace. The diffusion depth of the dopant may, in various embodiments, be in the range from about 0.1 μm to about 1 μm, e.g. in the range from about 0.3 μm to about 0.5 μm. In various embodiments, the diffusion may be provided in a tube furnace for processing the lightly doped regions. The diffusion may be carried out at a temperature in the range from about 700° degrees Celsius to about 1000° degrees Celsius, e.g. in the range from about 750° degrees Celsius to about 950° degrees Celsius, e.g. in the range from about 800° degrees Celsius to about 900° degrees Celsius, for example for a time period in the range from about 3 minutes to about 120 minutes, e.g. in the range from about 10 minutes to about 60 minutes, e.g. in the range from about 15 minutes to about 45 minutes.

Then, in 204, the material of the solidified emulsion (for example the phosphorus silicate glass (PSG)) may then be removed and an edge isolation may be carried out (for example by means of an one-side etching).

Then, in 206, a plurality of low-impedance regions may be formed, for example by means of a LCP process (LCP: Laser Chemical Processing: Laser beam led through a phosphorus acid-containing jet of water). It should be pointed out that any other conventional method for manufacturing the low-impedance regions (expressed differently the structures of the selective emitter) may be used in various embodiments. It can make sense depending on the used technology for forming the selective emitter to change the order of the process steps compared with the described embodiments. Thus, the described process order should not be understood in a limiting manner and other process orders are provided in alternative embodiments.

Subsequently, in 208, an anti-reflection coating may be deposited on the emitter-side exposed surface of the photovoltaic layer, for example made of silicon nitride or any arbitrary material suitable for it (for example by means of a CVD process for example by means of a plasma enhanced (PE) CVD process (PE-CVD) or by means of a PVD method, such as by means of sputtering). Thus, the surface damaged by the laser process may partly be healed and passivized again.

In a further embodiment, it is provided to carry out the LCP laser step for forming the selective emitter after the deposition of the anti-reflection layer. In this case, the liquid led laser beam locally opens the anti-reflection layer before the additional diffusion is carried out by the LCP process in the formed openings.

Subsequently, in 210, the front side metallization and the back side metallization are deposited by means of an economical silk-screen print process step. The front side metallization may include or consist of (solde-) pad structures, which are not connected with each other. A paste is used for the printing of the front side pads, which fires throughout the material of the anti-reflection coating (for example silicon nitride). In the mentioned example of the application of the LCP step after the deposition of the anti-reflection layer a paste, for example a metal paste, also can alternatively be used, which does not fire through the anti-reflection layer.

In a high temperature step, in various embodiment, in 212, the electrical contact is established between metallization and silicon. The back side metallization of the solar cell also will, if necessary, be produced by means of silk-screen printing and both contacts may be produced in a contact firing step (for example in a firing step, in which both the front side metallization and the back side metallization are fired-through at the same time).

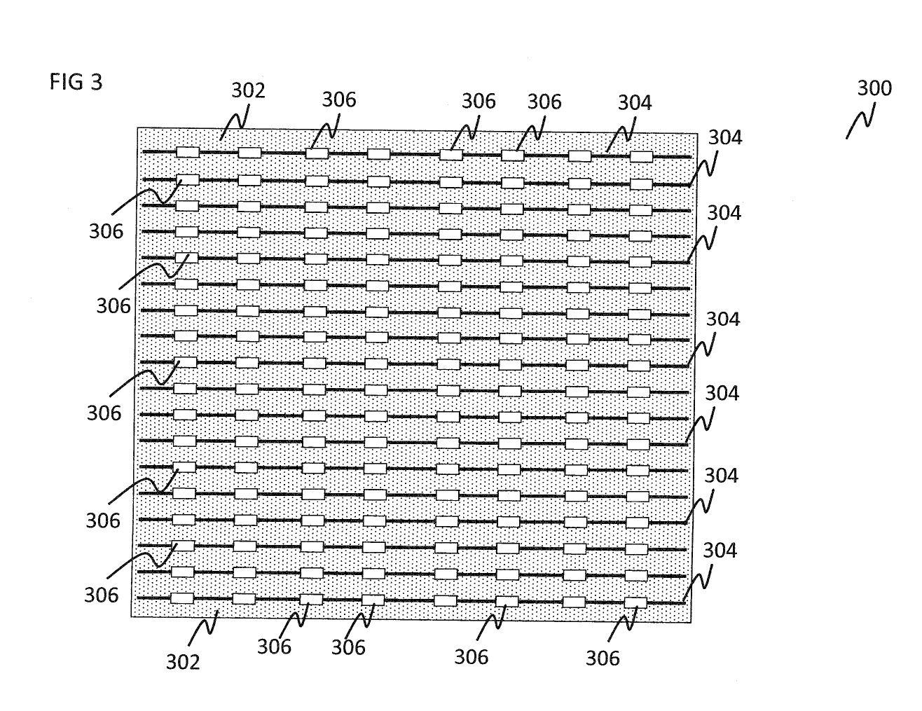

FIG. 3 shows a top view of a solar cell 300 in accordance with various embodiments. As shown in FIG. 3, the solar cell includes a base region (not shown), e.g. made of silicon, lightly doped with dopant of a first conductivity type, as described above. Furthermore, the solar cell includes an emitter region 302, e.g. made of silicon, e.g. doped with dopant of a second conductivity type, as described above. The second conductivity type is opposite to the first conductivity type. Furthermore, a plurality of regions 304 is provided in the emitter region 302, the plurality of regions 304 having a dopant concentration of the second conductivity type increased compared with the emitter region. These regions will in the following also referred to as regions of a selective emitter 304. In various embodiments, the plurality of regions 304 having an increased dopant concentration in the emitter region may include a plurality of line-shaped regions 304, which may run in parallel with each other, for example. Furthermore, a plurality of metallic soldering pads 306 is provided, wherein each soldering pad 306 is at least partially arranged (directly) on a region 304 having an increased dopant concentration, expressed differently, in physical contact with the region 304 having an increased dopant concentration.

In various embodiments, the soldering pads 306 are e.g. realized in the form of metal pads 306, which are not connected metallically with each other. The pad width is selected such that the soldering pads 306 partially cover, after the printing process, the low-impedance region, i.e. the selective emitter 304, e.g. are only arranged on the low-impedance region in the emitter region 302 and not on the higher-impedance lightly doped regions. This illustratively means that no soldering pad 306 of the plurality of soldering pads 306 includes a metallic connection to another soldering pad 306 of the plurality of soldering pads 306.

The soldering pads 306 include an arbitrary form in various embodiments. The soldering pads 306 may have a rectangular, square, perfectly circular or oval shape, for example. The soldering pads 306 may have a width in various embodiments in the range from about 0.1 mm to about 2 mm and a length in the range from about 0.1 mm to about 2 mm. At a perfectly circular form, the soldering pads 306 may have a diameter in the range from about 0.1 mm to about 2 mm.

In various embodiments, the soldering pads 306 have an extension in the direction of the lines of the selective emitter 304 smaller than, for example much smaller than, for example around a factor 2 to 5 smaller than the extension in the vertical direction thereto. This makes the alignment of the soldering pads 306 to the selective emitter structure 304 easier.

In various embodiments, a multiplicity of lines (for example running parallel with each other) of highly doped regions forming the selective emitter. By way of example, a number of highly-doped line-shape region may be in the range from about 20 to about 200 for example in the range from about 50 to about 120, for example in the range from about 60 to about 100, for example about 80 on the solar cell. The highly-doped line-shape regions may be arranged at a lateral distance to each other of for example at least 7 mm, for example at least 5 mm, for example at least 3.5 mm, for example at least 3.0 mm, for example at least 2.5 mm, for example at least 2.0 mm, for example at least 1.6 mm, for example at least 1.4 mm, for example at least 1.2 mm, for example at least 1.0 mm, for example at least 0.7 mm.

In various embodiments, the soldering pads 306 may be formed of a metal or a metal alloy and may include or consist of for example silver, copper, aluminium, nickel, tin, titanium, palladium, tantalum, gold, platinum or an arbitrary combination or alloy of these materials. In various embodiments, the soldering pads 306 may include or consist of silver or nickel. Furthermore, the soldering pads 306 may include or consist of a stack of different metals, for example nickel on titanium, silver on titanium, silver on nickel or for example a layer stack formed of titanium-palladium-silver, or a stack of titanium or nickel (in this case both work as diffusion bather) with copper arrangen thereon.

It should be pointed out that in the embodiments described above, the base region is e.g. p-doped, and the emitter region and the selective emitter are n-doped. It is, however, also provided in alternative embodiments that the base region is e.g. n-doped and the emitter region and the selective emitter are p-doped. In such embodiments, the soldering pads 306 may e.g. include or consist of aluminium or nickel, optionally with soldering material deposited on the aluminium (as an alternative, the soldering material may be deposited on the cell connectors, which are deposited and soldered later).

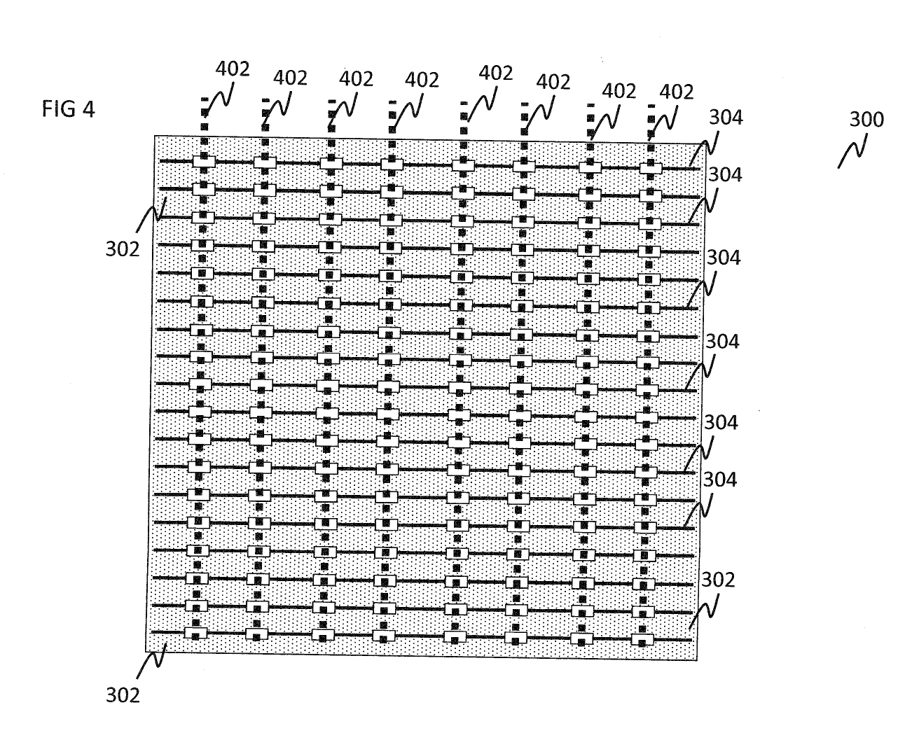

In various embodiments, cell connectors (for example cell connectors 402 in FIG. 4) are provided for electrical connection of a plurality of solar cells (e.g. connected in a series connection and/or a parallel connection), for example in the form of contact wires 402 or contact ribbons 402. The contact wires 402 or contact ribbons 402 for electrically connecting two solar cells 300 may be connected with the soldering pads 306 on the front side of a first solar cell of respective two adjacent solar cells and with the base contact on the back side of a second solar cell of respective two adjacent solar cells. The contact wires 402 or contact ribbons 402 are configured to collect and transmit electrical energy, which has been produced by the photovoltaic layer of a respective solar cell 300.

The contact wires 402 or contact ribbons 402 may include or consist of electrically conductive material, for example metallically conductive material. In various embodiments, the contact wires 402 or contact ribbons 402 may include or consist of one or a plurality of metallic materials, for example from one or a plurality of the following metals: Cu, Al, Au, Pt, Ag, Pb, Sn, Fe, Ni, Co, Zn, Ti, Mo, W and/or Bi. In various embodiments the contact wires 402 or contact ribbons 402 may include or consist of a metal, selected form a group consisting of: Cu, Au, Ag, Pb and Sn. The contact wires 402 or contact ribbons 402 may include an in principle arbitrary cross-sectional shape in various embodiments such as a round (for example perfectly circular) shape, an oval shape, a triangular shape, a rectangle shape (for example a square shape), or any other arbitrary suitable polygonial shape. The contact wires 402 or contact ribbons 402 may include a metal, e.g. nickel, copper, aluminium and/or silver or another suitable metal or metal alloy, for example brass. Furthermore, the contact wires 402 or contact ribbons 402 may coated with a metal or a metal alloy, for example with silver, Sn and/or nickel and/or a soldering coating, including or consisting of e.g. Sn, SnPb, SnCu, SnCuAg, SnPbAg, SnBi. In various embodiments, a multiplicity of contact wires 402 or contact ribbons 402 may be arranged over or on a respective solar cell 300, for example a number in the range from about 5 to about 60, for example in the range from about 10 to about 50, for example in the range from about 20 to about 40, for example approximately 30. In various embodiments, the contact wires 402 or contact ribbons 402 may be soldered with the soldering pads 306. In order to improve the binding of the contact wires 402 or contact ribbons 402 to the soldering pads 306 (also referred to as contact pads 306), the latter may be pre-soldered by means of a flow soldering method.

In various embodiments, at least a portion of the soldering pads 306 may extend over a plurality, however, not over all, regions 304 with increased dopant concentration in the emitter region.

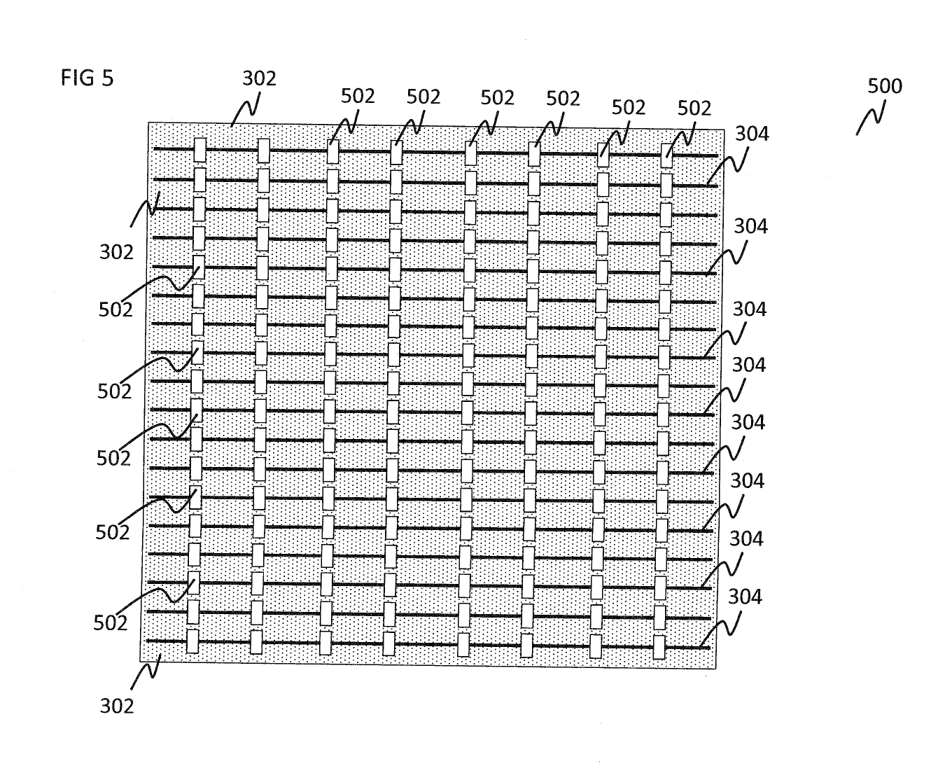

FIG. 5 shows a top view of a solar cell 500 in accordance with various embodiments. The solar cell 500 in accordance with FIG. 5 is very similar to the solar cell 300 in accordance with FIG. 3. For this reason, merely some differences between the solar cells will be explained in more detail below. With regard to the other components reference is made to the description of the solar cell 300 in accordance with FIG. 3.

In the solar cell 500 in accordance with FIG. 5, the soldering pads 502 are arranged with their longer extension crossways to the course direction of the low-impedance emitter regions 304. By doing this, the positioning of the soldering pads 502 relative to the highly-doped region 304 may be simplified still further.

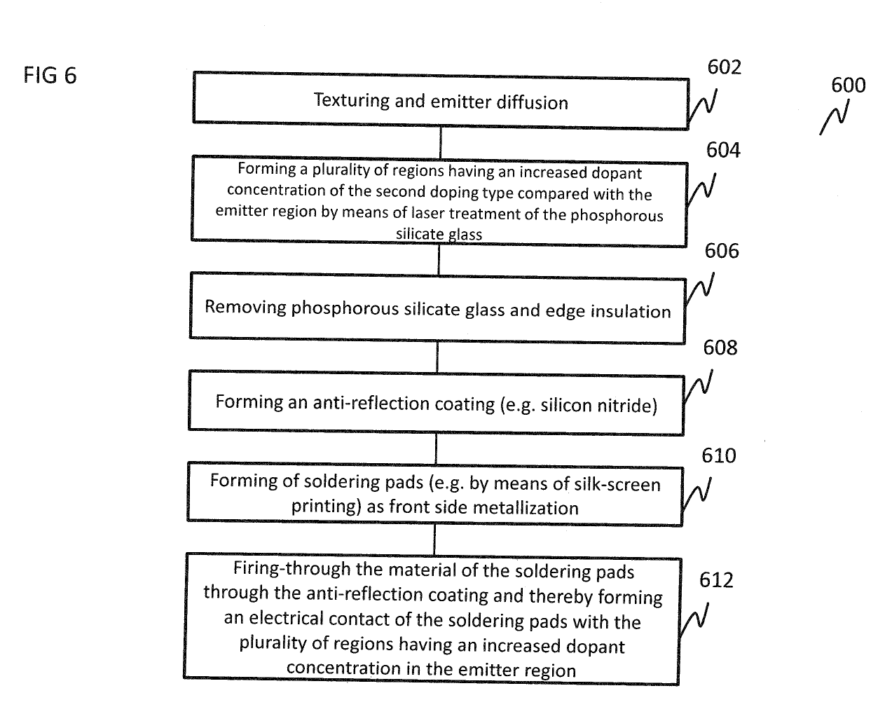

FIG. 6 shows a flowchart 600, in which a method for manufacturing a solar cell is illustrated in accordance with various embodiments.

In 602 the substrate with the photovoltaic layer may optionally be textured in a way known as such (for example by means of anisotropic etching in an alkaline solution or by means of etching in a acidic solution or by means of sawing V trenches into the solar cell substrate) and may be subjected to a so-called emitter diffusion, for example using an emulsion containing the dopant (for example phosphorus), which emulsion may be deposited on the (exposed) front side of the photovoltaic layer. The emitter diffusion is carried out in various embodiments in a furnace, for example a continuous annealing furnace. In various embodiments, the diffusion depth of the dopant lies in the range from about 0.1 μm to about 1 μm, for example in the range from about 0.3 μm to about 0.5 μm. In various embodiments, the diffusion may be provided by a tube furnace for processing the lightly-doped regions. The diffusion may be carried out at a temperature in the range from about 700° degrees Celsius to about 1000° degrees Celsius, for example in the range from about 750° degrees Celsius to about 950° degrees Celsius, for example in the range from about 800° degrees Celsius to about 900° degrees Celsius, for example for a time period in the range from about 3 minutes to about 120 minutes, for example in the range from about 10 minutes to about 60 minutes, for example in the range from about 15 minutes to about 45 minutes.

A plurality of low-impedance regions then may be formed in 604, for example by a local anneal step after the emitter diffusion. By means of a laser treatment on the dopant-containing layer (for example the phosphorus silicate glass (PSG)) additional phosphorus can locally be introduced into the semiconductor layer. The sheet resistance may be reduced locally.

Then, in 606, the material of the dopant-containing layer (for example the phosphorus silicate glass (PSG)) may be removed and an edge isolation may be carried out (for example by means of a one-side etching).

Subsequently, in 608, an anti-reflection coating may be deposited on the emitter-side exposed surface of the photovoltaic layer, for example made of silicon nitride or any arbitrary material suitable for this (for example by means of a CVD process, for example by means of a plasma enhanced (PE) CVD process (PE-CVD) or by means of a PVD method, such as by means of sputtering). Thus, the surface damaged by the laser process may be partly healed and passivized again.

Subsequently, in 610, e.g. by means of an economic silk-screen print process step, the front side metallization and the back side metallization may be deposited. The front side metallization may in this case include or consist of (solder) pad structures, which are not connected with each other. A paste is used for the printing of the front side pads, which paste fires through the anti-reflection coating (for example silicon nitride).

In a high temperature step, in various embodiments, in 612, the electrical contact is established between metallization and silicon. The back side metallization of the solar cell will, if applicable, be produced by means of silk-screen printing and both contacts may be produced in one contact firing step (for example in one firing step, in which both the front side metallization and the back side metallization are fired-through at the same time).

The selective emitter structure clearly is formed in the embodiments represented in FIG. 6 before the phosphorus glass removal.

In this case, a front side paste may be used for the printing of the soldering pads 306, which fires through the silicon nitride. It may be advantageously in this case to choose the soldering pads 306 so small that only low-impedance emitter regions 304 are (physically) contacted and no lightly-doped emitter region 302.

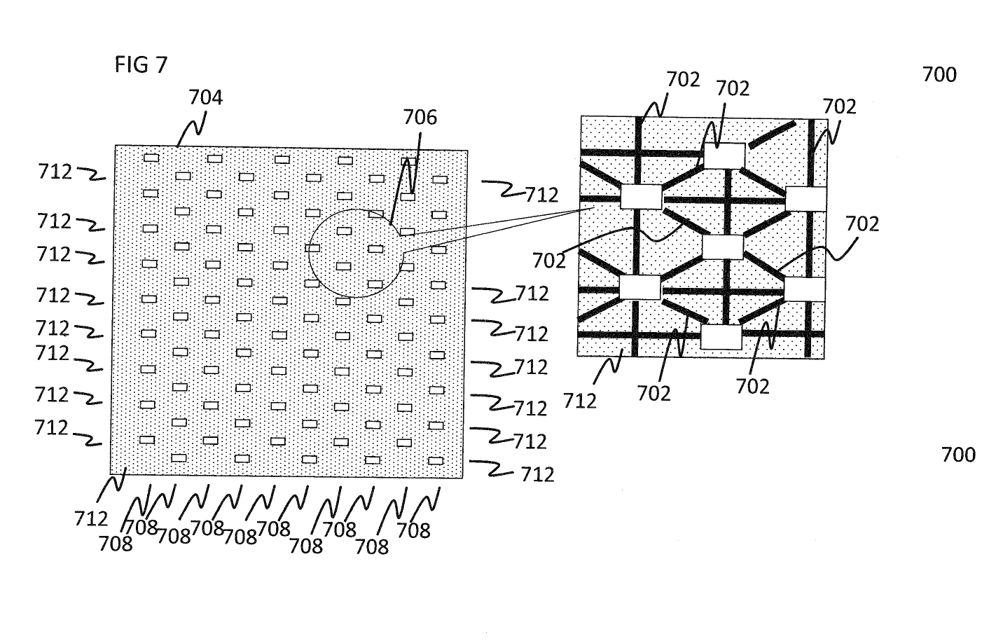

FIG. 7 shows a top view of an emitter region 704 of a solar cell 700 in accordance with various embodiments. As shown in FIG. 7 (and well visible in the augmented region 706), in various embodiments, line-shape higher-doped regions 702 in for example a radial structure of the higher-doped regions 702 (and thus low-impedance regions 702 which form the selective emitter) are provided, e.g. introduced into lightly-doped regions 712 (expressed differently high-impedance regions 712). In these embodiments, the number of provided soldering pads (not shown in FIG. 7) may be reduced. This is made possible by arranging the soldering pads 306 in columns 708 and rows 710, wherein the arrangement is such that soldering pads of neighbouring columns are arranged offset respectively by one row. Thus, in these embodiments, illustratively, a soldering pad 306 is arranged along one row only on every second crossing point of a highly-doped region 304 of the respective row 710 with a highly-doped region of a respective column 708. In this way, for example a rhomboid or diagonal-shaped soldering pad pattern arises (optionally with additional star-shaped highly-doped regions, which connect the soldering pads 306 with each other).

Another advantage of these embodiments may be seen in that a particularly low-impedance emitter is produced in the contact points (also referred to as touch points or contact locations) 704 of the higher-doped regions 702 by means of a repeatedly carried out processing in crossing points 704. The contact resistance formed thereby should therefore be particularly low.

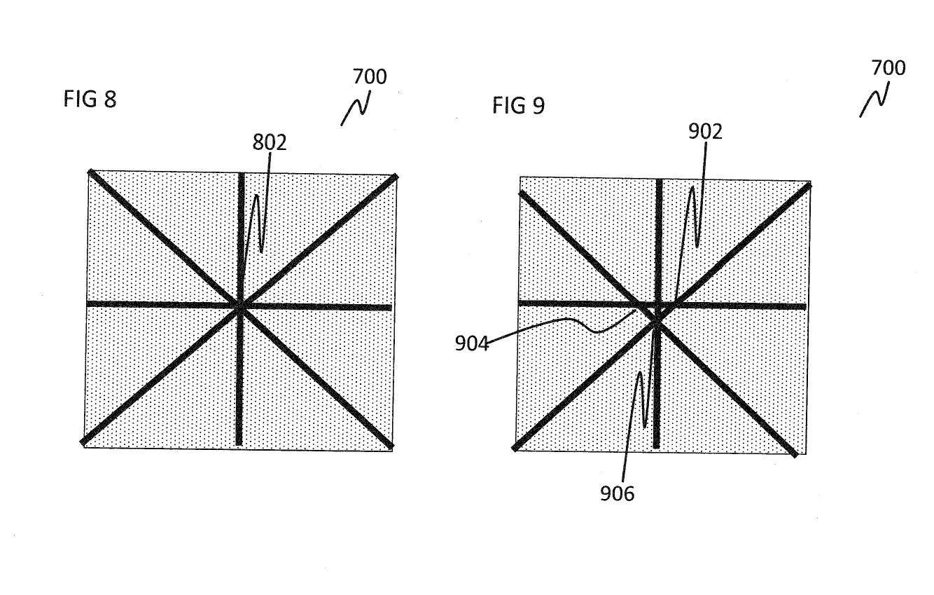

FIG. 8 shows a crossing point 802 of the emitter region 702 from FIG. 7, onto which a soldering pad 306 should be deposited. A special implementation of the embodiment shown in FIG. 8 shows FIG. 9. In the embodiments shown in FIG. 9, the contact points 902, 904, 906—thus the crossing points 902, 904, 906 of the low-impedance regions in the emitter region—may be widened in a targeted manner. The lines (i.e. the line-shaped higher-doped regions 702) do not meet in a point but in a region, for example in a plurality of contact points 902, 904, 906, for example in three contact points 902, 904, 906.

The following table shows parameters of a possible implementation of an embodiment for a solar cell in the format 156 mm×156 mm with line-shaped low-impedance emitter regions:

| | | | |
|---|---|---|---|
| Width low-impedance | 50 μm | Number Pads | 80 × 20 |
| emitter region | | | |
| Sheet resistance low- | 30 ohm/sq | Size contact pad | 250 × 250 μm² |
| impedance emitter region | | | |
| Number of lines low- | 80 | Diameter contact | 200 μm |
| impedance emitter region | | wires (round) | |

It should be pointed out that for different materials and dimensions of the individual components the parameters may considerably differ from the parameters indicated in the table.

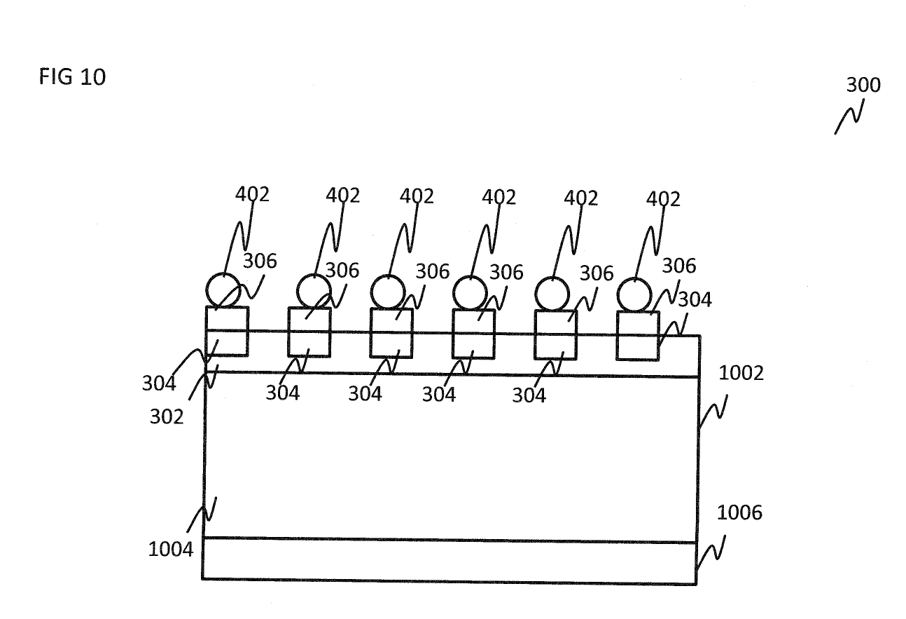

FIG. 10 shows a cross-sectional view of the solar cell 300 of FIG. 3 in accordance with various embodiments. FIG. 10 shows a photovoltaic layer 1002 with the base region 1004 and the emitter region 302, in which region 302 the highly-doped regions 304 are formed (expressed differently the regions of the selective emitter 304). Furthermore, FIG. 10 shows a plurality of soldering pads 306 and cell connectors 402 soldered thereon. Furthermore, the back side metallization 1006 is shown.

In various embodiments, a solar cell is provided. The solar cell may include a base region doped with dopant of a first doping type; an emitter region doped with dopant of a second doping type, wherein the second doping type is opposite to the first doping type; a plurality of regions in the emitter region having an increased dopant concentration of the second doping type compared with the emitter region; and a plurality of metallic soldering pads, wherein each soldering pad is at least partially arranged on a region having an increased dopant concentration.

In various embodiments, at least one metallic soldering pad of the plurality of metallic soldering pads may have no metallic connection to the at least one other metallic soldering pad. In various embodiments, the plurality of regions having an increased dopant concentration in the emitter region may include a plurality of line-shaped regions. In various embodiments, the plurality of regions having an increased dopant concentration in the emitter region may include a sheet resistance in the range from about 30 Ω/sq to about 80 Ω/sq. In various embodiments, the emitter region may include a sheet resistance in the range from about 80 Ω/sq to about 200 Ω/sq. In various embodiments, a plurality or multiplicity of separate soldering pads may be arranged along a respective region having an increased dopant concentration in the emitter region. In various embodiments, at least some of the soldering pads may extend over a plurality of, but not all, regions having an increased dopant concentration in the emitter region. In various embodiments, the soldering pads may have a length, which is larger than their width; and the soldering pads may be arranged such that their length extension is substantially perpendicular to the length extension of the region having an increased dopant concentration in the emitter region being contacted by the respective soldering pad. In various embodiments, the soldering pads may be arranged in columns and rows, wherein the arrangement may be such that soldering pads of adjacent columns are arranged offset by respectively one row. In various embodiments, at least a part of the regions having an increased dopant concentration in the emitter region may be arranged such that at least two of the regions having an increased dopant concentration in the emitter region touch each other in a touching point; wherein at least a part of the soldering pads may be arranged on a respective touching point.

In various embodiments, a solar module is provided. The solar module may include a multiplicity of solar cells. Each solar cell may include a base region doped with dopant of a first doping type; an emitter region doped with dopant of a second doping type, wherein the second doping type is opposite to the first doping type; a plurality of regions in the emitter region having an increased dopant concentration of the second doping type compared with the emitter region; and a plurality of separate metallic soldering pads, which are arranged along a respective region having an increased dopant concentration in the emitter region, wherein each soldering pad is at least partially arranged on a region having an increased dopant concentration; wherein at least a part of neighbouring solar cells are electrically connected with each other by means of cell connectors.

In various embodiments, a method for manufacturing a solar cell is provided. The method may include forming a base region doped with dopant of a first doping type; forming an emitter region doped with dopant of a second doping type, wherein the second doping type is opposite to the first doping type; forming a plurality of regions in the emitter region having an increased dopant concentration of the second doping type compared with the emitter region; and forming a plurality of separate metallic soldering pads, which are arranged along a respective region having an increased dopant concentration in the emitter region, wherein each soldering pad is at least partially arranged on a region having an increased dopant concentration, such that a solar cell is manufactured.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A solar cell, comprising:
a base region doped with dopant of a first doping type;
an emitter region doped with dopant of a second doping type, wherein the second doping type is opposite to the first doping type;
a plurality of regions in the emitter region having an increased dopant concentration of the second doping type compared with the emitter region; and
a plurality of separate metallic soldering pads, which are arranged along a respective region having an increased dopant concentration in the emitter region, wherein each soldering pad is at least partially arranged on a region having an increased dopant concentration.

2. The solar cell of claim 1,
wherein at least one metallic soldering pad of the plurality of metallic soldering pads has no metallic connection to the at least one other metallic soldering pad.

3. The solar cell of claim 1,
wherein the plurality of regions having an increased dopant concentration in the emitter region comprises a plurality of line-shaped regions.

4. The solar cell of claim 1,
wherein the plurality of regions having an increased dopant concentration in the emitter region comprises a sheet resistance in the range from about 30 Ω/sq to about 80 Ω/sq.

5. The solar cell of claim 1,
wherein the emitter region comprises a sheet resistance in the range from about 80 Ω/sq to about 200 Ω/sq.

6. The solar cell of claim 1,
wherein at least some of the soldering pads extend over a plurality of, but not all, regions having an increased dopant concentration in the emitter region.

7. The solar cell of claim 1,
wherein the soldering pads have a length, which is larger than their width; and
wherein the soldering pads are arranged such that their length extension is substantially perpendicular to the length extension of the region having an increased dopant concentration in the emitter region being contacted by the respective soldering pad.

8. The solar cell of claim 1,
wherein the soldering pads are arranged in columns and rows, wherein the arrangement is such that soldering pads of adjacent columns are arranged offset by respectively one row.

9. The solar cell of claim 1,
wherein at least a part of the regions having an increased dopant concentration in the emitter region are arranged such that at least two of the regions having an increased dopant concentration in the emitter region touch each other in a touching point;
wherein at least a part of the soldering pads are arranged on a respective touching point.

10. A solar module comprising:
a multiplicity of solar cells, each solar cell comprising:
a base region doped with dopant of a first doping type;
an emitter region doped with dopant of a second doping type, wherein the second doping type is opposite to the first doping type;
a plurality of regions in the emitter region having an increased dopant concentration of the second doping type compared with the emitter region; and
a plurality of separate metallic soldering pads, which are arranged along a respective region having an increased dopant concentration in the emitter region, wherein each soldering pad is at least partially arranged on a region having an increased dopant concentration;
wherein at least a part of neighboring solar cells are electrically connected with each other by means of cell connectors.

11. A method for manufacturing a solar cell, the method comprising:
forming a base region doped with dopant of a first doping type;
forming an emitter region doped with dopant of a second doping type, wherein the second doping type is opposite to the first doping type;
forming a plurality of regions in the emitter region having an increased dopant concentration of the second doping type compared with the emitter region; and
forming a plurality of separate metallic soldering pads, which are arranged along a respective region having an increased dopant concentration in the emitter region, wherein each soldering pad is at least partially arranged on a region having an increased dopant concentration, such that a solar cell is manufactured.
